(19) United States
(12) Patent Application Publication
(10) Pub. No.: US 2006/0175664 A1
(43) Pub. Date: Aug. 10, 2006

(54) Semiconductor constructions, and methods of forming metal silicides

(75) Inventors: Nirmal Ramaswamy, Boise, ID (US); Paul J. Castrovillo, Boise, ID (US); Joel A. Drewes, Boise, ID (US)

Correspondence Address: WELLS ST. JOHN P.S., 601 W. FIRST AVENUE, SUITE 1300, SPOKANE, WA, 99201, US

(73) Assignee: Micron Technology, Inc.

(21) Appl. No.: 11/053,475

(22) Filed: Feb. 7, 2005

(51) Int. Cl. H01L 29/40; H01L 21/44

(52) U.S. Cl. 257/384; 438/586; 438/682; 438/683; 257/768; 257/770

(57) ABSTRACT

The invention includes methods of forming metal silicide. A layer consisting essentially of one or more metal nitrides is formed directly against a silicon-containing region. A layer comprising one or more metals is formed over the one or more metal nitrides. Silicon is transferred from the silicon-containing region, through the one or more metal nitrides, and to the one or more metals to convert at least some of the one or more metals into metal silicides. In particular aspects, titanium is formed over tantalum nitride, and the silicon is transferred into the titanium to convert the titanium into titanium silicide. The invention also includes semiconductor constructions having a layer consisting essentially of titanium silicide directly against a layer consisting essentially of tantalum nitride.

### TECHNICAL FIELD

The invention pertains to methods of forming metal silicides, such as, for example, titanium silicide; and also pertains to semiconductor constructions comprising metal silicides.

### BACKGROUND OF THE INVENTION

Silicides, such as, for example, titanium silicide, are commonly utilized electrically conductive materials in semiconductor wafer integrated circuit fabrication. Such materials are utilized, for example, as capping layers over underlying conductively-doped polysilicon material to form electrically conductive lines or interconnects. Silicide materials can also be utilized at contact bases, and specifically can be provided to be between a silicon substrate and one or more conductive materials.

Titanium silicide (TiSi₂) occurs in two different crystalline structures or phases, which are referred to as C49 and C54 phases. The C49 phase is base-center orthorhombic, while the C54 phase is face-centered orthorhombic. The C54 phase occurs in the binary phase diagram while the C49 phase does not. The C49 phase is therefore considered to be meta-stable. The C54 phase is a more densely-packed structure than the C49 phase. The C54 phase also has lower resistivity (higher conductivity) than the C49 phase.

The C49 phase typically forms at lower temperatures during a typical refractory metal silicide formation anneal (e.g., at from about 500° C. to about 600° C.) and transforms to the C54 phase at higher temperatures (e.g., at temperatures of greater than or equal to about 650° C.). The formation of the high resistivity C49 phase has been observed to be almost inevitable due to the lower activation energies associated with it (2.1 to 2.4 eV) which arises from the lower surface energy of the C49 phase compared to that of the more thermodynamically stable C54 phase.

Due at least in part to its greater conductivity, the C54 phase is more desirable as contact or conductive line cladding material than the C49 phase. Continued semiconductive wafer fabrication has achieved denser and smaller circuitry, making silicide layers thinner and narrower in each subsequent processing generation. As the silicide layers become thinner and narrower, the ratio of surface area to volume of material to be transformed from the C49 phase to the C54 phase increases. This requires ever increasing activation energies to cause the desired phase transformation, which translates to higher anneal temperatures to effect the desired phase transformation. Unfortunately, heating a silicide layer to a higher temperature can result in undesired precipitation and agglomeration of silicon in such layer, and also adversely exposes the wafer being processed to undesired and ever increasing thermal exposure. The processing window for obtaining low resistance silicide phases for smaller line widths and contacts continues to be reduced, making fabrication difficult.

It would be desirable to develop methods of forming metal silicides, and particularly to develop methods which facilitate the C49 to C54 phase transformation in titanium silicide films. It would also be desirable to develop methods which initially, or which appear initially, to form a substantial percentage of titanium silicide in the C54 phase during deposition to minimize or eliminate subsequent dedicated or separate anneal processing and separate equipment. It would also be desirable to develop methods and structures which alleviate high-temperature agglomeration of silicide materials.

### SUMMARY OF THE INVENTION

In one aspect, the invention includes a method of forming metal silicide. A substrate is provided, with such substrate having a silicon-containing region. A first layer is formed directly against the silicon-containing region. The first layer consists essentially of one or more metal nitrides. A second layer is formed over the first layer. The second layer comprises one or more metals. Silicon is transferred from the silicon-containing region, through the first layer and to the second layer to convert at least some of the second layer into one or more metal silicides.

In one aspect, the invention encompasses a method of forming titanium silicide. A substrate is provided, with the substrate having a silicon-containing region. A layer consisting essentially of tantalum nitride is formed directly against the silicon-containing region. A titanium-containing layer is formed over the layer consisting essentially of tantalum nitride. Silicon is transferred from the silicon-containing region, through the tantalum nitride, and to the titanium of the titanium-containing layer to convert at least some of the titanium-containing layer into titanium silicide.

In one aspect, the invention includes a semiconductor construction. The construction comprises a substrate having a silicon-containing region. The construction also comprises a layer consisting essentially of tantalum nitride directly against the silicon-containing region, and comprises a layer consisting essentially of titanium silicide directly against the layer consisting essentially of tantalum nitride.

### BRIEF DESCRIPTION OF THE DRAWINGS

Preferred embodiments of the invention are described below with reference to the following accompanying drawings.

FIG. 1 is a diagrammatic, cross-sectional view of a semiconductor wafer fragment at a preliminary processing stage of an exemplary aspect of the present invention.

FIG. 2 is a view of the FIG. 1 wafer fragment shown at a processing stage subsequent to that of FIG. 1.

FIG. 3 is view of the FIG. 1 wafer fragment shown at a processing stage subsequent to that of FIG. 2.

FIG. 4 is a view of the FIG. 1 wafer fragment shown as a preliminary processing stage in accordance with another aspect of the invention.

FIG. 5 is a view of the FIG. 4 wafer fragment shown at a processing stage subsequent to that of FIG. 4.

FIG. 6 is a diagrammatic, cross-sectional view of a semiconductor wafer fragment shown at a preliminary processing stage in accordance with yet another aspect of the present invention.

FIG. 7 is a view of the FIG. 6 wafer fragment shown at a processing stage subsequent to that of FIG. 6.

FIG. 8 is a view of the FIG. 6 wafer fragment shown at a processing stage subsequent to that of FIG. 7.

FIG. 9 is a view of the FIG. 6 wafer fragment shown at a processing stage subsequent to that of FIG. 8.

FIG. 10 is a view of the FIG. 6 wafer fragment shown at a processing stage subsequent to that of FIG. 9.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

One aspect of the invention is a recognition that it can be advantageous to form a thin layer of tantalum nitride between titanium and a silicon-containing material, and to thereafter incorporate silicon from the silicon-containing material into titanium silicide formed from the titanium. The tantalum nitride can increase the amount of C54 phase present in the titanium silicide, and can also alleviate agglomeration of the titanium silicide at high temperatures.

A possible mechanism by which the tantalum nitride increases the amount of C54 phase present in the titanium silicide formed thereover is that the tantalum nitride may act as a template for C54 phase formation. More specifically, the TaN can lead to formation of a C40 phase tantalum silicide (which is a hexagonal atomic array with a stacking order of ABC). Since C54-phase TiSi₂ is a face-centered orthorhombic structure with hexagonal-arrayed atomic ABCD stacking, the tantalum silicide can be a template for nucleation of C54-phase titanium silicide. A possible mechanism by which the tantalum nitride may alleviate agglomeration is that the tantalum nitride may act as a filter (or barrier) to reduce migration of silicon into the titanium silicide. The mechanisms are provided herein to assist the reader in understanding various aspects of the present invention, but it is to be understood that the invention is not limited to such mechanisms except to the extent, if any, that the mechanisms are expressly recited in the claims that follow.

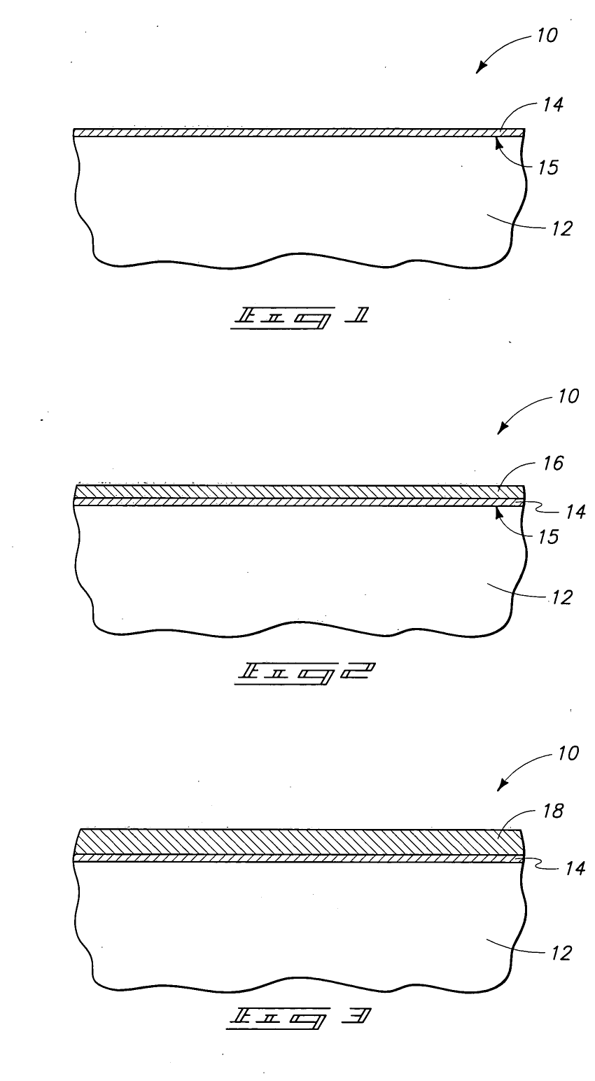

An exemplary aspect of the present invention is described with reference to FIGS. 1-3. Referring initially to FIG. 1, a semiconductor wafer fragment 10 is illustrated at a preliminary processing stage. Wafer fragment 10 comprises a semiconductor substrate 12. Substrate 12 can comprise, for example, a monocrystalline silicon wafer lightly background doped with p-type dopant. To aid in interpretation of the claims that follow, the terms “semiconductive substrate” and “semiconductor substrate” are defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

A layer 14 is formed over substrate 12. Layer 14 can comprise, consist essentially of, or consist of one or more metal nitrides, and in particular aspects will comprise, consist essentially of, or consist of tantalum nitride. An interface 15 is between substrate 12 and layer 14.

Substrate 12 can have various conductive, insulative and/or semiconductor structures provided therein at various processing stages during the fabrication of integrated circuitry. It is desired, however, that substrate 12 have a silicon-containing region adjacent the interface 15, and more specifically, it is desired that layer 14 be formed directly against a silicon-containing region of the substrate. Such silicon-containing region can comprise, consist essentially of, or consist of silicon. The silicon can be in any of various forms, including, for example, single crystal, polycrystalline, and/or amorphous.

Layer 14 can, in particular aspects, have a thickness from at least about 5 Å to less than or equal to about 50 Å, and it can be preferred that layer 14 have a thickness of from at least about 5 Å to less than or equal to about 10 Å. Layer 14 is preferably thin enough to allow silicon migration from the silicon-containing region below layer 14 into a metal layer subsequently formed over layer 14 so that a silicide can be formed from the metal layer, and yet thick enough to control silicon migration into the silicide ultimately formed over layer 14 so that agglomeration of the silicide can be avoided.

Layer 14 can be formed by any suitable processing method, including, for example, chemical vapor deposition, atomic layer deposition, sputter deposition, etc. In some aspects, it can be preferred that layer 14 be formed by atomic layer deposition, as such can form a thin, uniform and high-quality layer.

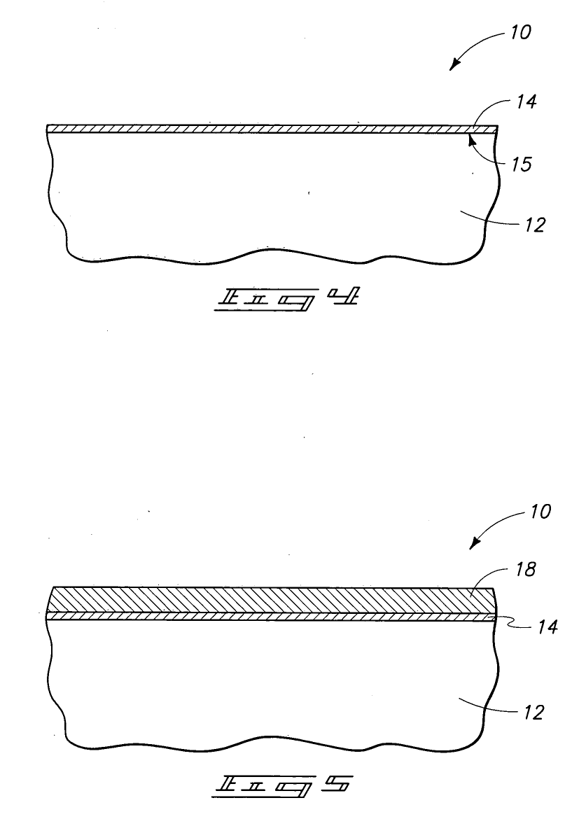

Referring next to FIG. 2, a layer 16 is formed over and in direct physical contact with layer 14. Layers 14 and 16 can be referred to as a first layer and a second layer, respectively, to distinguish the layers from one another. Layer 16 comprises, consists essentially of, or consists of one or more metals. In particular aspects, layer 16 can comprise, consist essentially of, or consist of titanium, and in such aspects layer 16 can be referred to as a titanium-containing layer.

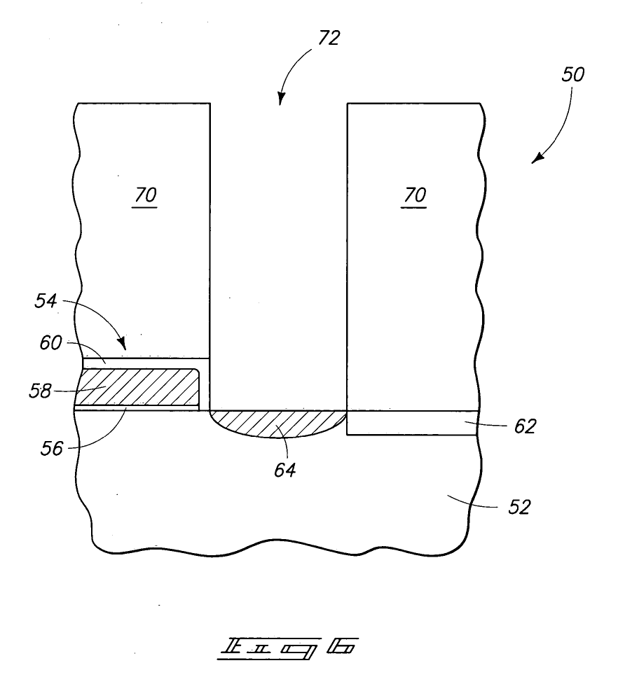

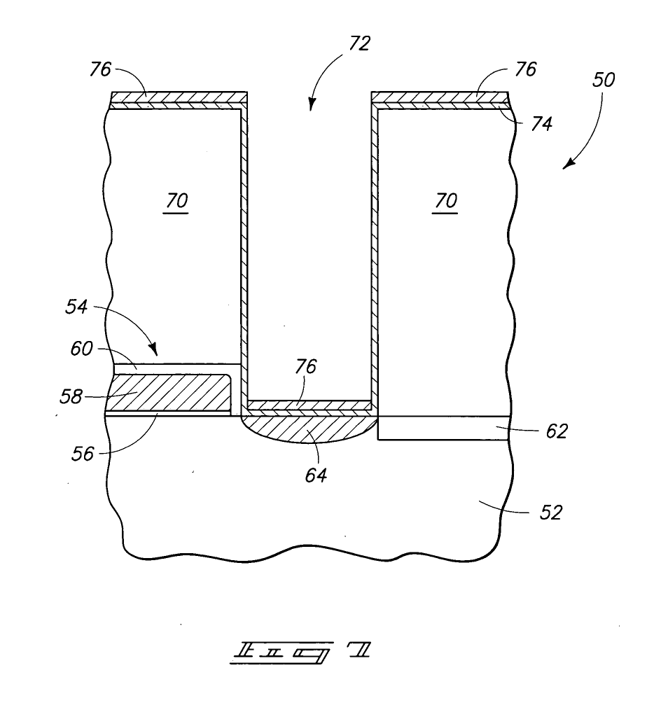

Layer 16 can be formed by any suitable method, including, for example, sputter deposition, chemical vapor deposition and/or atomic layer deposition. In the aspect of the invention of FIGS. 1-3, layer 16 is deposited utilizing a relatively low temperature process so that the layer is elemental metal as-deposited. Layer 16 is subsequently converted to a silicide with an appropriate anneal (discussed below with reference to FIG. 3). It is to be understood that the invention encompasses other aspects (discussed with reference to FIGS. 4 and 5) in which the layer 16 is formed with a higher-temperature deposition process so that the metal of layer 16 converts to metal silicide during formation of layer 16. If layer 16 is titanium, the relatively low temperature deposition process of FIG. 2 can be, for example, physical vapor deposition conducted at a processing temperature which keeps layer 16 at or below 500° C. during the deposition of layer 16.

Referring next to FIG. 3, construction 10 is subjected to an anneal that causes silicon to transfer from the silicon-containing region beneath layer 14, through layer 14, and into the metal of layer 16 (FIG. 2) to form metal silicide 18. In particular aspects, a titanium-containing layer 16 is converted into a layer 18 comprising, consisting essentially of, or consisting of titanium silicide. In the shown aspect of the invention, an entirety of layer 16 has been converted into metal silicide 18, but it is to be understood that the invention encompasses other aspects (not shown) in which only some of layer 16 is converted into metal silicide. Layer 18 is shown to be thicker than layer 16 to indicate that silicon has been incorporated into the layer 16 during conversion of layer 16 into metal silicide.

If layer 18 is titanium silicide, the anneal utilized to form the titanium silicide can be conducted at a temperature of greater than 400° C., and typically will be conducted at a temperature of greater than or equal to about 600° C., with about 800° C. being an exemplary temperature.

In applications in which layer 18 is titanium silicide, such titanium silicide can advantageously have a relatively high ratio of C54 phase to C49 phase, with the typical ratio being greater than or equal to 50%. In contrast, if titanium silicide were formed in processing conditions similar to those of FIGS. 1-3, but without the layer 14 of metal nitride (with a typical metal nitride being tantalum nitride), the ratio of C54 phase to C49 phase would typically be less than or equal to about 10%. Also, the metal nitride 14 can enhance the stability of the overlying titanium silicide-containing material 18 at high temperatures. For instance, material 18 will be resistant to agglomeration at temperatures which would typically cause agglomeration in the absence of metal nitride 14 (such as, for example, temperatures of from about 800° C. to about 1000° C., with temperatures in excess of 900° C. being particularly problematic for structures lacking the metal nitride 14).

Although the processing of FIGS. 1-3 forms silicide-containing layer 18 with an anneal occurring after formation of metal-containing layer 16, it is to be understood that the invention also encompasses aspects in which the conversion to the metal silicide occurs during formation of the metal over metal nitride-containing material 14. Exemplary methods of forming metal silicide during formation of a metal-containing material over the metal nitride-containing layer are described with reference to FIGS. 4 and 5. Identical numbering will be used in referring to FIGS. 4 and 5 as was utilized above in describing FIGS. 1-3.

Referring to FIG. 4, construction 10 is illustrated at a preliminary processing stage. Construction 10 of FIG. 4 is identical to the construction 10 of FIG. 1, and accordingly comprises the substrate 12, metal-nitride-containing material 14, and interface 15 described above with reference to FIG. 1.

Referring next to FIG. 5, construction 10 is illustrated after formation of metal-silicide-containing layer 18 over metal-nitride-containing layer 14. The metal-silicide-containing layer can comprise, consist essentially of, or consist of titanium silicide; and the metal-nitride-containing layer can comprise, consist essentially of, or consist of tantalum nitride. In such aspects, titanium-silicide-containing layer 18 is formed by deposition of titanium over tantalum-nitride-containing layer 14 at a sufficiently high temperature to transfer silicon from the underlying silicon-containing region within substrate 12, through layer 14 and into the deposited titanium. Thus, titanium silicide formation occurs during the deposition of the titanium. Such can be accomplished by conducting the titanium deposition at a processing temperature sufficient to maintain layer 14, the deposited titanium, and the silicon-containing region underlying layer 14, at 400° C. or above. An exemplary process which can maintain such processing temperature is chemical vapor deposition of titanium over layer 14.

The construction of FIG. 5 is identical to the construction of FIG. 3.

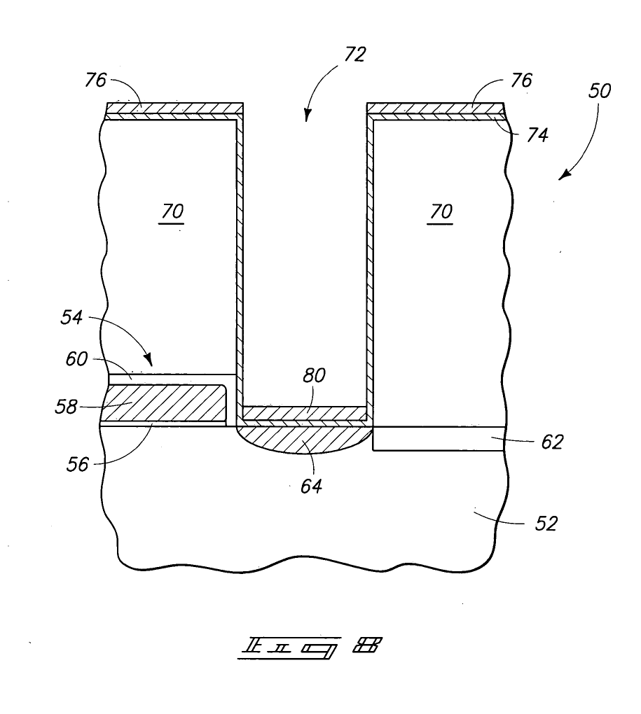

The methodology of the present invention can be incorporated into various semiconductor device fabrication processes to form metal-silicide-containing materials. An exemplary process is described with reference to FIGS. 6-10.

Referring initially to FIG. 6, a semiconductor construction 50 is illustrated at a preliminary processing stage. Construction 50 comprises a substrate 52 analogous to the substrate 12 discussed above with reference to FIGS. 1-5. Substrate 52 can thus comprise, for example, monocrystalline silicon lightly-doped with background p-type dopant.

A transistor gate 54 is diagrammatically illustrated over substrate 52. Gate 54 comprises an insulator region 56 directly over substrate 52. Such gate insulator region can comprise, for example, silicon dioxide, and can be referred to as gate oxide.

The gate also comprises an electrically conductive region 58 over insulator region 56. Conductive region 58 can comprise one or more electrically conductive materials, including, for example, conductively-doped silicon, elemental metal, and/or metal compositions, such as, for example, metal silicides. If conductive region 58 comprises metal silicide, such metal silicide can be formed in accordance with aspects of the invention described above with reference to FIGS. 1-5, and can, for example, comprise, consist essentially of, or consist of titanium silicide.

An insulative structure 60 surrounds the top and sidewalls of conductive material 58. Insulative structure 60 can correspond to, for example, an electrically insulative cap and an electrically-insulative sidewall spacer. The cap and spacer can be formed from the same electrically insulative materials as one another, or from different electrically insulative materials. If the cap and spacer comprise the same insulative material, then the cap and spacer will merge into a single electrically insulative structure extending over the top and sidewall of conductive material 58, as shown. In some aspects, the insulative cap and spacer can comprise silicon nitride or silicon dioxide.

Transistor gate 54 corresponds to the gate of a field effect transistor, as will be recognized by persons of ordinary skill in the art. Such persons will also recognize that gate 54 can be incorporated into a flash device by forming a control gate (not shown) over the shown conductive gate region 58, and spaced from such conductive gate region by appropriate insulative materials. The methodology described with reference to FIGS. 6-10 can be applied to standard field effect transistor devices as well as to FLASH devices, and/or to numerous other integrated circuit devices, as will be recognized by persons of ordinary skill in the art.

An isolation region 62 is formed within substrate 52. Isolation region 62 can correspond to, for example, a shallow trench isolation region, and accordingly can comprise, consist essentially of, or consist of silicon dioxide.

A conductively-doped diffusion region 64 extends within substrate 52, and is aligned between gate 54 and isolation region 62. Such can be accomplished utilizing conventional methodologies, such as, for example, implanting conductivity-enhancing dopant into single crystal silicon of a bulk silicon substrate. Also, although not shown, it is to be understood that conductively-doped region 64 can have an extension which extends under a portion of gate 54. Such extension can correspond to a lightly-doped diffusion region, while the shown region 64 would typically correspond to a heavily-doped diffusion region. Region 64 can be referred to as a source/drain region, in that region 64 corresponds to a source/drain of a transistor device comprising gate 54. As will be recognized by persons of ordinary skill in the art, the transistor device will typically comprise a second source/drain region on an opposing side of the gate from source/drain region 64, and gatedly connected to source/drain region 64 through a channel region beneath gate 54. The electrical coupling between the source/drain regions is operably controlled by electrical flow through gate 54.

An electrically insulative material 70 is over substrate 52, and such insulative material has an opening 72 extending therethrough to the conductively-doped source/drain region 64. In some aspects of the invention, opening 72 can have a very high aspect ratio, such as, for example, an aspect ratio of at least about 5:1, or even at least about 7:1. It is frequently found to be difficult to form silicide at the bottom of high-aspect-ratio openings utilizing conventional prior art processes, and methodology of the present invention can overcome difficulties associated with the prior art processes. Silicide is ultimately desired at the bottom of opening 72 prior to formation of electrically conductive materials within the opening, as will be recognized by persons of ordinary skill in the art.

Referring to FIG. 7, a metal-nitride-containing layer 74 is formed over insulative material 70 and within opening 72. Layer 74 can, for example, comprise, consist essentially of, or consist of tantalum nitride.

Layer 74 lines a bottom periphery of the opening, and is formed directly against a silicon-containing region corresponding to conductively-doped region 64.

Metal-nitride-containing layer 74 is shown lining sidewalls of opening 70, but it is to be understood that the material of layer 74 may or may not adhere to such sidewalls depending on the deposition conditions utilized for forming material of layer 74, and depending on the compositions of layer 74 and the sidewalls. Regardless, the material of layer 74 would be formed along the bottom periphery of the opening.

A metal-containing material 76 is formed over material 74. Material 76 is specifically shown formed over the upper surfaces of insulative material 70 and along the bottom of opening 72. The material 76 is not shown lining the sidewalls of opening 72, but it is to be understood that the material 76 may or may not line the sidewalls of the opening depending on the deposition process utilized to form material 76, and depending on the compositions of material 76 and the sidewalls. Regardless, material 76 forms a layer along the bottom of the opening. Material 76 can, for example, comprise, consist essentially of, or consist of titanium.

Layers 74 and 76 can be formed utilizing processing analogous to that described above with reference to FIGS. 1 and 2.

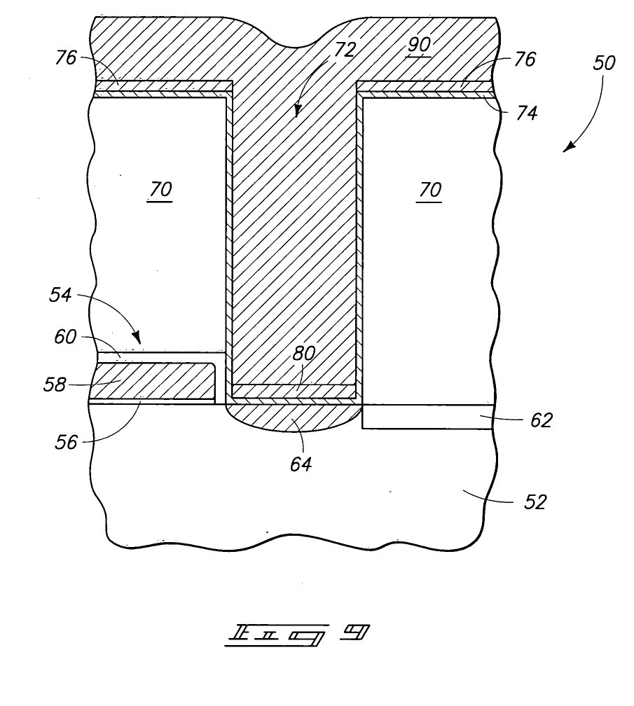

Referring next to FIG. 8, construction 50 is subjected to an anneal which transfers silicon from silicon-containing region 64 through layer 74 and into the layer 76 (FIG. 7) along the bottom of the opening to convert layer 76 to a new material 80. Such new material comprises, consists essentially of, or consists of metal silicide, such as, for example, titanium silicide.

The conversion of material 76 at the bottom of the opening to material 80 can be accomplished utilizing anneal conditions analogous to those discussed above with reference to FIG. 3. The material 76 at the top of opening 72 is shown to not be converted to material 80, such as would occur if there was not a silicon-containing region at the top of insulative material 70 suitable for transferring silicon into the material 76 during the anneal.

Although the aspect of the invention described with reference to FIGS. 7 and 8 forms metal-containing material 76 at one processing stage, and then subsequently converts the material to silicide-containing material 80 with an appropriate anneal, it is to be understood that the invention also encompasses aspects analogous to FIGS. 4 and 5 in which the metal-containing material converts to silicide during the formation of the metal-containing material along the bottom of the opening. Accordingly, metal-containing material 76 of FIG. 7 can, in some aspects, be deposited at a sufficiently high temperature that the material converts to material 80 during the deposition of the metal-containing material, rather than being converted with an anneal subsequent to the formation of the metal-containing material.

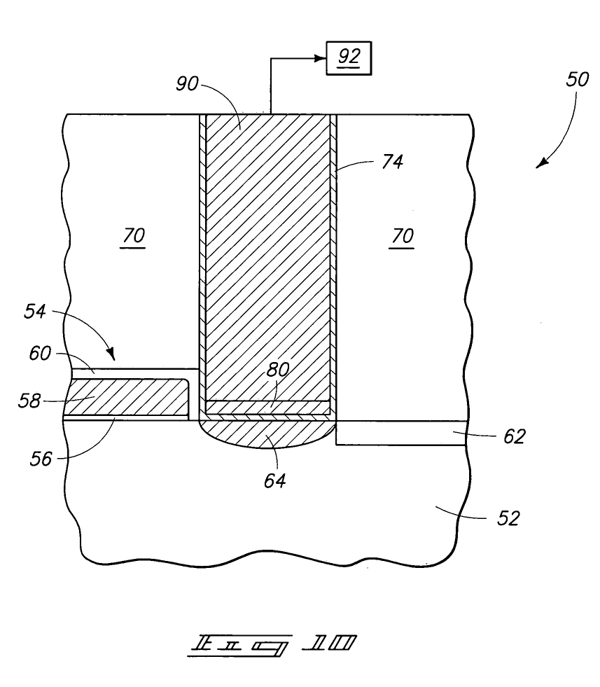

Referring next to FIG. 9, a conductive mass 90 is formed over substrate 52 and within opening 72 to fill the opening. Mass 90 can comprise one or more electrically conductive materials. In particular aspects, mass 90 will comprise metal, such as, for example, tungsten and/or will comprise conductively-doped semiconductor materials, such as, for example, conductively-doped silicon.

Referring next to FIG. 10, construction 50 is subjected to planarization to remove materials 74, 76 and 90 from over insulative mass 70. Such planarization can also remove some of insulative mass 70 to lower an uppermost surface of insulative mass 70. The planarization can be accomplished utilizing any suitable processing, including, for example, chemical-mechanical polishing.

The conductive materials 90, 74 and 80 remaining at the processing stage of FIG. 50 form a conductive plug which electrically couples conductively-doped source/drain region 64 to circuitry 92. Specifically, conductive material 90 is electrically connected with source/drain region 64 through layer 74 and silicide material 80, and the conductive material 90 is also electrically coupled to the circuitry 92.

Circuitry 92 can correspond to any circuitry which is ultimately desired to be electrically coupled with source/drain region 64 of the transistor device 54. In some aspects, transistor device 54 will be incorporated into a dynamic random access memory (DRAM) unit cell, and circuitry 92 will correspond to a charge storage device, such as, for example, a device configured for a capacitive charge storage (i.e., a capacitor).

Although a conductive plug is shown formed within opening 72 in the processing described above, it is to be understood that at least some of the material formed within the opening can also be incorporated into a circuit device other than a conductive plug, such as, for example, a capacitor. Thus, a container capacitor can be formed within the opening and electrically connected to source/drain region 64 through silicide-containing material 80 and nitride-containing material 74.

An advantage of utilizing methodology of the present invention with high aspect ratio openings can be that the silicides formed in accordance with methodologies of the present invention can better withstand the high-temperature processing commonly-associated with high aspect ratio openings than can conventional silicides formed by prior art processes.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

The invention claimed is:

1. A method of forming metal silicide, comprising:
providing a substrate having a silicon-containing region;
forming a first layer directly against the silicon-containing region, the first layer consisting essentially of one or more metal nitrides;
forming a second layer over the first layer, the second layer comprising one or more metals; and
transferring silicon from the silicon-containing region, through the first layer and to the second layer to convert at least some of the second layer into one or more metal silicides.

2. The method of claim 1 wherein the silicon-containing region is a single crystal region of said substrate.

3. The method of claim 1 wherein the metal of said one or more metal nitrides is different than the metal of said one or more metals of the second layer.

4. The method of claim 1 wherein said one or more metal silicides comprise titanium silicide.

5. The method of claim 1 wherein said first layer consists essentially of tantalum nitride.

6. A method of forming titanium silicide, comprising:
providing a substrate having a silicon-containing region;
forming a layer consisting essentially of tantalum nitride directly against the silicon-containing region;
forming a titanium-containing layer over the layer consisting essentially of tantalum nitride; and
transferring silicon from the silicon-containing region, through the tantalum nitride and to the titanium of the titanium-containing layer to convert at least some of the titanium-containing layer into titanium silicide.

7. The method of claim 6 wherein the silicon-containing region is a single crystal region of said substrate.

8. The method of claim 6 wherein the layer consisting essentially of tantalum nitride has a thickness of from at least about 5 Å to less than or equal to about 20 Å.

9. The method of claim 6 wherein the layer consisting essentially of tantalum nitride has a thickness of from at least about 5 Å to less than or equal to about 10 Å.

10. The method of claim 6 wherein the transferring of the silicon occurs during the forming of the titanium-containing layer.

11. The method of claim 6 wherein the transferring of the silicon occurs after the forming of the titanium-containing layer, and comprises an anneal of the titanium-containing layer and silicon-containing region at a temperature of at least about 400° C.

12. The method of claim 11 wherein the anneal temperature is greater than or equal to about 600° C.

13. The method of claim 11 wherein the anneal temperature is greater than or equal to about 800° C.

14. The method of claim 6 wherein:
the silicon-containing region is a conductively-doped source/drain region of a transistor device;
an insulative material is over the substrate and has an opening extending therethrough to the silicon-containing region;
the titanium silicide is formed along a bottom periphery of the opening; and
conductive materials are formed within the opening and over the titanium silicide, said conductive materials being electrically connected to the conductively-doped source/drain region through the titanium silicide and the tantalum nitride.

15. The method of claim 14 wherein the transistor device is a field effect transistor.

16. The method of claim 14 wherein the transistor device is a FLASH device.

17. The method of claim 14 wherein the conductive materials electrically couple with capacitive charge storage.

18. The method of claim 14 wherein the opening has an aspect ratio of at least about 5:1.

19. The method of claim 14 wherein the opening has an aspect ratio of at least about 7:1.

20. A semiconductor construction, comprising:
a substrate having a silicon-containing region;
a layer consisting essentially of tantalum nitride directly against the silicon-containing region; and
a layer consisting essentially of titanium silicide directly against the layer consisting essentially of tantalum nitride.

21. The construction of claim 20 wherein the silicon-containing region is a single crystal region of said substrate.

22. The construction of claim 20 wherein the silicon-containing region is a conductively-doped source/drain region of a transistor device.

23. The construction of claim 20 wherein the layer consisting essentially of tantalum nitride has a thickness of from at least about 5 Å to less than or equal to about 20 Å.

24. The construction of claim 20 wherein the layer consisting essentially of tantalum nitride has a thickness of from at least about 5 Å to less than or equal to about 10 Å.

25. The construction of claim 20 wherein:
the silicon-containing region is a conductively-doped source/drain region of a transistor device;
an insulative material is over the substrate and has an opening extending therethrough to the silicon-containing region;
the titanium silicide is along a bottom periphery of the opening; and
conductive materials are within the opening and over the titanium silicide, said conductive materials being electrically connected to the conductively-doped source/drain region through the titanium silicide and the tantalum nitride.

26. The construction of claim 20 wherein the transistor device is a field effect transistor.

27. The construction of claim 20 wherein the conductive materials electrically couple with capacitive charge storage.

28. The construction of claim 20 wherein the opening has an aspect ratio of at least about 5:1.

29. The construction of claim 20 wherein the opening has an aspect ratio of at least about 7:1.
